(19) United States
(12) Patent Application Publication
(10) Pub. No.: US 2026/0164817 A1
(43) Pub. Date: Jun. 11, 2026

(54) METHOD OF FORMING IMAGE SENSOR INCLUDING AIR GRID

(71) Applicant: Applied Materials, Inc., Santa Clara, CA (US)

(72) Inventors: Xing Chen, Dublin, CA (US); Michael Patrick Chudzik, Mountain View, CA (US); Siddarth Krishnan, San Jose, CA (US); Kun Li, Delmar, NY (US); Jeremiah Hebding, Feura Bush, NY (US); Zhen Xu, Cupertino, CA (US); Kwangduk Douglas Lee, Redwood City, CA (US); Yubin Zhang, Singapore (SG)

(73) Assignee: Applied Materials, Inc., Santa Clara, CA (US)

(21) Appl. No.: 18/975,797

(22) Filed: Dec. 10, 2024

(51) Int. Cl. H10F 39/00

(52) U.S. Cl. CPC H10F 39/024; H10F 39/8053

(57) ABSTRACT

Disclosed herein are approaches for forming an air grid of an image sensor. One method may include depositing a first fill material within a first plurality of trenches to form a plurality of grid structures, wherein the first plurality of trenches is formed through an oxide layer formed over a substrate, wherein the fill material is formed along a sidewall and a bottom surface of each trench of the plurality of trenches, and wherein a void is formed within the fill material. The method may further include forming a second plurality of trenches through the oxide layer and the first fill material.

### FIELD OF THE DISCLOSURE

The embodiments of the present disclosure relate to image sensors and, in particular, to methods of forming image sensors including an air grid.

### BACKGROUND OF THE DISCLOSURE

Image sensors, such as, complementary metal oxide semiconductor (CMOS) image sensors (CIS), capture images by detecting light coming from the source. The color of incident light is captured by using a color filter having a plurality of color pixels. Color filters absorb unwanted wavelengths to filter and transmit only the desired color to the photodetector of the corresponding color channel, e.g., red, green, and blue.

The color pixels are typically arranged using a metal or oxide grid. However, metal and oxide grids prevent light transmission through a combination of absorption and reflection. Additionally, with the continuing push towards smaller pixel sizes (e.g., below 0.6 um), crosstalk between pixels becomes a significant issue. The use of air gap grids between color filters is one approach to address these drawbacks. However, existing solutions for air gap grids suffer from non-ideal geometry, low reliability, and high cost.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method of forming an image sensor may include depositing a first fill material within a first plurality of trenches to form a plurality of grid structures, wherein the first plurality of trenches are formed through an oxide layer formed over a substrate, wherein the fill material is formed along a sidewall and a bottom surface of each trench of the plurality of trenches, and wherein a void is formed within the fill material. The method may further include forming a second plurality of trenches through the oxide layer and the first fill material.

In another aspect, a method of forming a plurality of grid structures of an image sensor may include forming a first plurality of trenches through an oxide layer, wherein the oxide layer is formed over a substrate. The method may further include depositing a first fill material within the first plurality of trenches to form a plurality of grid structures, wherein the fill material is formed along a sidewall and a bottom surface of each trench of the plurality of trenches, and wherein a void within one or more trenches of the first plurality of trenches is enclosed by the fill material. The method may further include forming a second plurality of trenches through the oxide layer and the first fill material.

In yet another aspect, a method of forming an image sensor may include depositing a first fill material within a first plurality of trenches to form a plurality of grid structures, wherein the first plurality of trenches define an interconnected trench array, wherein the first plurality of trenches are formed through an oxide layer formed over a substrate, wherein the fill material is formed along a sidewall and a bottom surface of each trench of the plurality of trenches, and wherein a void is formed within the fill material. The method may further include forming a second plurality of trenches through the oxide layer and the first fill material.

### BRIEF DESCRIPTION OF THE DRAWINGS

The accompanying drawings illustrate exemplary approaches of the disclosure, including the practical application of the principles thereof, as follows:

FIG. 1 illustrates a cross-sectional side view of a first plurality of trenches formed through a stack of layers of an example image sensor, according to embodiments of the present disclosure;

FIG. 2A illustrates a cross-sectional side view of the first plurality of trenches formed through the stack of layers of the example image sensor following removal of one or more layers of the stack of layers, according to embodiments of the present disclosure;

FIG. 2B is a top view of the first plurality of trenches formed through the stack of layers of the example image sensor following removal of one or more layers of the stack of layers, according to embodiments of the present disclosure;

FIG. 3A illustrates a top view of the example image sensor following formation of a first fill material, according to embodiments of the present disclosure;

FIG. 3B illustrates a cross-sectional side view of the example image sensor along cutting plane B-B′ of FIG. 3A following formation of the first fill material, according to embodiments of the present disclosure;

FIG. 3C illustrates a cross-sectional side view of the example image sensor along cutting plane C-C′ of FIG. 3A following formation of the first fill material, according to embodiments of the present disclosure;

FIG. 4 illustrates an optional liner barrier formed over the first fill material, according to embodiments of the present disclosure;

FIG. 5A illustrates a top view of the example image sensor following formation of a second fill material, according to embodiments of the present disclosure;

FIG. 5B illustrates a cross-sectional side view of the example image sensor along cutting plane B-B′ of FIG. 5A following formation of the second fill material, according to embodiments of the present disclosure;

FIG. 5C illustrates a cross-sectional side view of the example image sensor along cutting plane C-C′ of FIG. 5A following formation of the second fill material, according to embodiments of the present disclosure;

FIG. 6 illustrates a cross-sectional side view of a second plurality of trenches formed through the example image sensor, according to embodiments of the present disclosure;

FIG. 7 illustrates a cross-sectional side view of the example image sensor following formation of a liner within the second plurality of trenches, according to embodiments of the present disclosure;

FIG. 8 illustrates a cross-sectional side view of the example image sensor following formation of a color filter layer, according to embodiments of the present disclosure; and

FIG. 9 illustrates a diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods of forming a Complementary Metal Oxide Semiconductor image sensor (CIS) in accordance with the present disclosure will now be described more fully hereinafter with reference to the accompanying drawings, where various embodiments are shown. The methods may be embodied in many different forms and are not to be construed as being limited to the embodiments set forth herein. Instead, these methods are provided so the disclosure will be thorough and complete, and will fully convey the scope of the methods to those skilled in the art.

Disclosed herein are techniques to form an “air gap” grid or array across a CIS. Embodiments of the disclosure utilize a multi-step lithography trench formation process and a multi-step fill material deposition process to precisely control geometry of the air gap grid. Following formation of the multi-step fill material deposition process, an air gap/void may be present within one or more grid structures of the air gap grid. In some embodiments, a liner may be formed within one or more trenches adjacent the grid structures to enhance the structural integrity of the air gap grid and to increase resistance to moisture, which increases reliability.

In some approaches, the multi-step fill material deposition process may first include a low-temperature oxide (LTO) deposition, which may be optimized to form the air gap and to control the location at which the LTO joins together above the air gap. Optimization may be achieved by tuning one or more of gas flow, temperature, and deposition rate. Following the LTO deposition, a second fill material may be formed over the air gaps of the air grid. In some embodiments, a high-aspect-ratio process (HARP), such as a plasma-enhanced atomic layer deposition (PE-ALD) or plasma-enhanced chemical vapor deposition (PECVD), may be used to pinch-off, or seal, an intersection area above the trenches to achieve seamless gap fill in the high-aspect-ratio trenches. Advantageously, the HARP does not significantly alter the size and/or geometry of the air gaps already formed within the trenches. In some embodiments, the HARP may be performed at an elevated temperature (e.g., approximately 400° C.-540 ° C.), which helps achieve a quick sealing of the material above of the air gap without unnecessary additional material deposition.

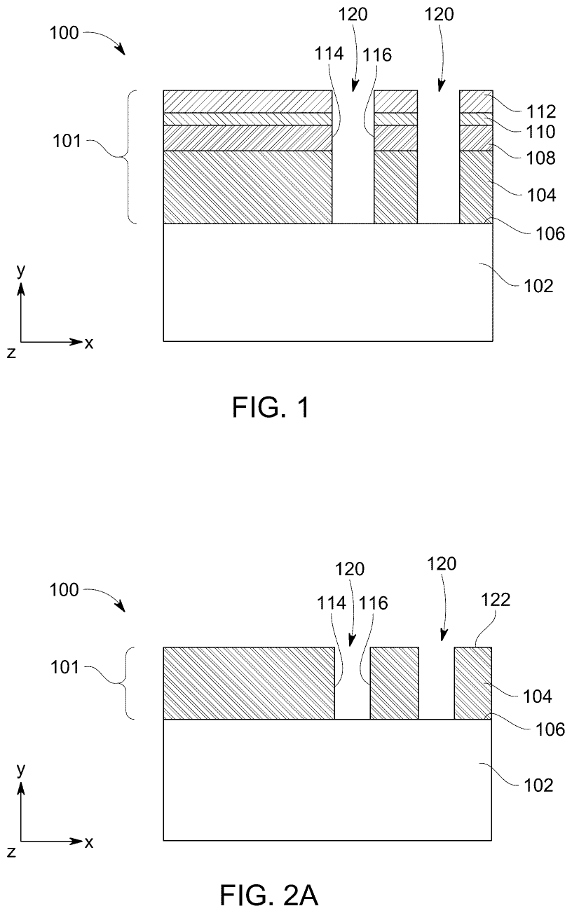

FIG. 1 illustrates an image sensor (hereinafter “sensor”) 100 at one stage of processing according to embodiments of the present disclosure. As shown, the sensor 100 may include a stack of layers 101 formed over the substrate 102, wherein the stack of layers 101 may include an oxide layer 104 directly atop an upper surface 106 of the substrate 102, a dielectric layer 108 formed over the oxide layer 104, an anti-reflective coating (ARC) layer 110 formed over the dielectric layer 108, and a photoresist 112 formed over the ARC layer 110. Although non-limiting, the oxide layer 104 may be tetraethoxysilane (TEOS) or silicon dioxide (SiO2), the dielectric layer 108 may be an organic dielectric layer (ODL), and the ARC layer 110 may be a silicon-containing ARC layer.

The substrate 102 may include a semiconductor substrate made of a suitable semiconductor material. For example, the substrate 102 may include a monocrystalline silicon or a monocrystalline silicon-containing material. In some implementations, the substrate 102 may include P-type impurities. Several fabrication processes are performed on the substrate 102, and a plurality of photoelectric conversion elements (not shown) may be formed on or in the substrate 102. The photoelectric conversion elements may be separated from one another by isolation structures.

As further shown, a first plurality of trenches 120 may be formed through the stack of layers 101. In some embodiments, the first plurality of trenches 120 may be formed using a vertical etch, which continues to the upper surface 106 of the substrate 102. Each of the first plurality of trenches 120 may be defined by a first sidewall 114, a second sidewall 116, and the upper surface 106 of the substrate 102. Although non-limiting, the first sidewall 114 and the second sidewall 116 may be generally parallel to one another. Although only two trenches 120 are depicted, it will be appreciated that additional trenches 120 may be present across the sensor 100.

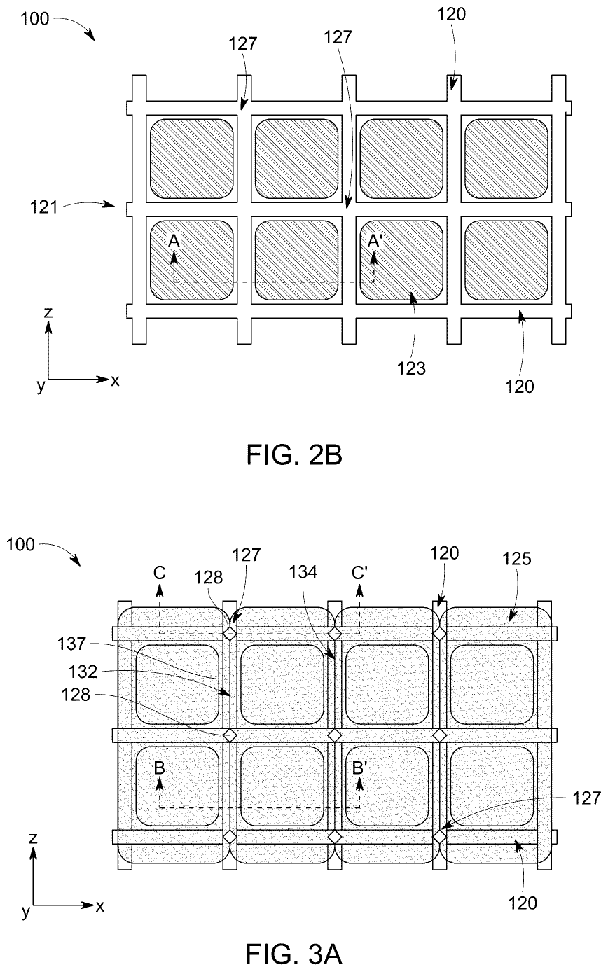

As shown in FIG. 2A, a portion of the stack of layers 101 may then be removed from the sensor 100 following formation of the first plurality of trenches 120. More specifically, the dielectric layer 108, the ARC layer 110, and the photoresist 112 may be removed selective to an upper surface 122 of the oxide layer 104 using, for example, an ashing process.

FIG. 2B is a top view of the sensor 100 following the ashing process. As shown, the first plurality of trenches 120 may extend in both the x-direction and z-direction, thus defining an interconnected trench array 121, wherein the first plurality of trenches 120 may intersect with one another at intersection areas 127. In this non-limiting example, the first plurality of trenches 120 define a 2×4 array of pixel areas 123, wherein the first plurality of trenches 120 provide optical isolation between adjacent pixel areas 123. Other array sizes are possible in alternative examples. Although not shown, each of the pixel areas 123 may later receive a color filter (e.g., red, green, blue or yellow color filter), which is covered by a micro-lens for gathering/converging incident light. The sensor 100 along cutting plane A-A′ is shown in FIG. 2A.

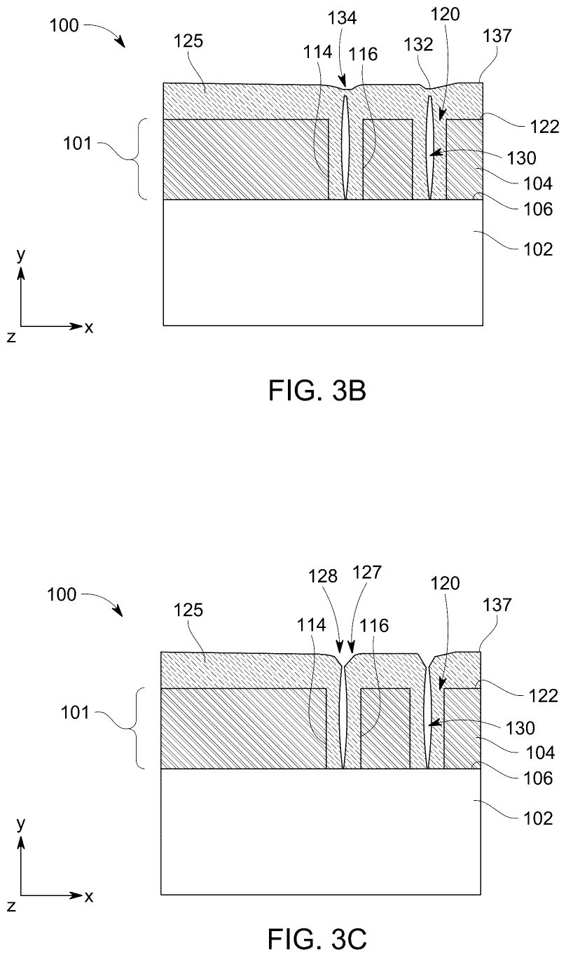

FIG. 3A illustrates a top view, and FIGS. 3B and 3C illustrate cross-sectional side views along cutting planes B-B′ and C-C′, respectively, of the image sensor 100 following formation of a first fill material 125. As shown in FIGS. 3A-3B, the first fill material 125 may be formed over the oxide layer 104, including within each of the first plurality of trenches 120. As shown, the first fill material 125 may be formed along the first sidewall 114 and the second sidewall 116 of the first plurality of trenches 120, and along the upper surface 106 of the substrate 102. The first fill material 125 may be further formed along the upper surface 122 of the oxide layer 104. However, the first fill material 125 may not entirely fill each of the first plurality of trenches 120. Instead, as best shown in FIG. 3B, an air gap, or void 130, may be present within each of the first plurality of trenches 120. The void 130 may be disposed over the substrate 102, and the shape of the void 130 may be defined by the first fill material 125 and the first plurality of trenches 120. The air within the void 130 may have a relatively low refractive index of 1.0 or below, for example.

The first fill material 125 may fully enclose the void 130 by forming a “pinched-off” capping area 132 of the first fill material 125 above the void 130. An upper surface 137 of the capping area 132 may define a recess or dip 134 at the intersections of the first fill material 125 formed due to a difference in the depths of the first plurality of trenches 120 relative to the upper surface 122 of the oxide layer 104. In some embodiments, each void 130 may generally extend to the upper surface 106 of the substrate 102. In other embodiments, one or more of the voids 130 may be separated from the upper surface 106 of the substrate 102 by a lower portion of the first fill material 125.

As shown in FIGS. 3A and 3C, a gap or recess 128 in the first fill material 125 may be present at the intersection areas 127 of the first plurality of trenches 120 in some embodiments. The recesses 128 may represent areas of incomplete formation of the first fill material 125 due to the relatively larger area of the intersection areas 127. Said another way, unlike over the voids 130, the first fill material 125 may not pinch-off at the intersection areas 127 of the first plurality of trenches 120. As will be described below, a second fill material process may be performed to address the recesses 128 in the first fill material 125.

In some embodiments, the first fill material 125 may be a low-temperature oxide (LTO), which is deposited directly atop the upper surface 122 of the oxide layer 104. Deposition of the LTO may be optimized to control the formation and dimensions of the air gap, and to control at what height the LTO joins together above the void 130. Optimization may be achieved by tuning one or more of gas flow rate (e.g., of silane (SiH4)), temperature, and deposition rate.

In various embodiments, the first fill material 125 may be SiO2, silicon nitride (Si3N4), tantalum pentoxide (Ta2O5), hafnium oxide (HfO2), aluminum oxide (Al2O3), or titanium oxide (TiO2). In other embodiments, the first fill material 125 may include zinc sulfide (ZnS), gallium nitride (GaN), zinc selenide (ZnSe), or a combination thereof.

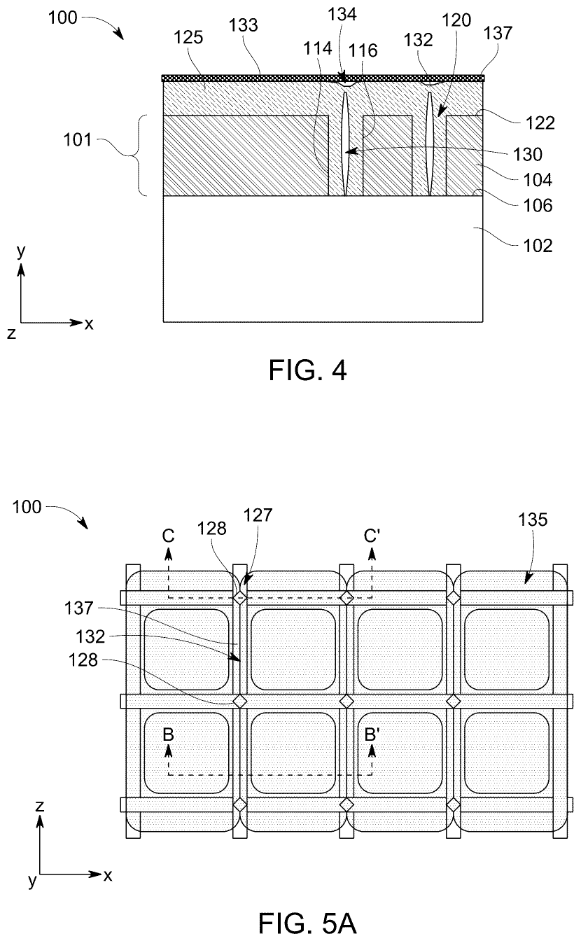

As shown in FIG. 4, an optional liner barrier 133 may be formed over the first fill material 125 in some embodiments. The liner barrier 133 may be a nitride, e.g., SiN, which is deposited (e.g., via ALD) over the first fill material 125.

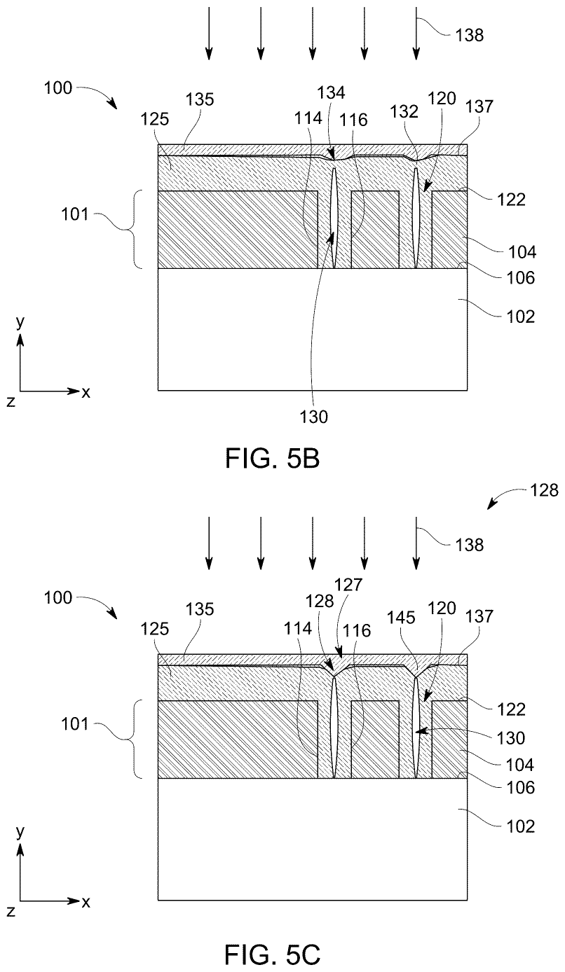

FIG. 5A illustrates a top view, and FIGS. 5B and 5C illustrate cross-sectional side views along cutting planes B-B′ and C-C′, respectively, of the image sensor 100 following formation of a second fill material 135 over the first fill material 125. As shown in FIGS. 5A and 5B, the second fill material 135 is formed over the capping area 132, above the voids 130. In some embodiments, the second fill material 135 may be formed using a plasma-enhanced HARP (PEHARP) 138, which may be a plasma-enhanced chemical vapor deposition (PECVD) in which a local plasma is applied to affect the deposition of the second fill material 135. More specifically, the PEHARP 138 may include performing a thermal (non-plasma) CVD process followed by a plasma treatment at low pressure, wherein the thermal CVD and the plasma treatment are performed in a same process chamber. In some embodiments, the thermal CVD and the plasma treatment may also be repeated cyclically, as desired.

In one example, a TEOS and Trioxygen (O₃) associated thermal SiO₂ film deposition followed by a localized helium (He) plasma treatment can fill the dips 134 formed in the upper surface 137 of the capping area 132 of the first fill material 125. The plasma treatment not only improves the film quality, such as wet-etch-rate, but also provides further tunability of the size of the capping area 132. The second fill material 135 may be further formed using a high deposition rate with tunable stress, which helps achieve a quick pinch-off and densification in the upper surface 137 of the capping area 132 with minimal additional material deposition in the capping area 132. In some embodiments, the PEHARP 138 may be performed at an elevated temperature (e.g., approximately 400° C.-540 ° C.) to satisfy the various thermal budgets. Advantageously, the PEHARP 138 does not significantly alter the size and/or geometry of the voids 130 already formed within the first plurality of trenches 120.

As shown in FIGS. 5A and 5C, the second fill material 135 is further formed over the recesses 128 present in the first fill material 125 at the intersection areas 127 of the first plurality of trenches 120. That is, the second fill material 135 may fully enclose the recesses 128 by forming a capping area 145 of the second fill material 135 at the intersection areas 127.

In some embodiments, the second fill material 135 and the first fill material 125 may be the same, e.g., SiO2. In other embodiments, the second fill material 135 may be Si3N4, Ta2O5, HfO2, Al2O3, TiO2, ZnS, GaN, ZnSe, or a combination thereof.

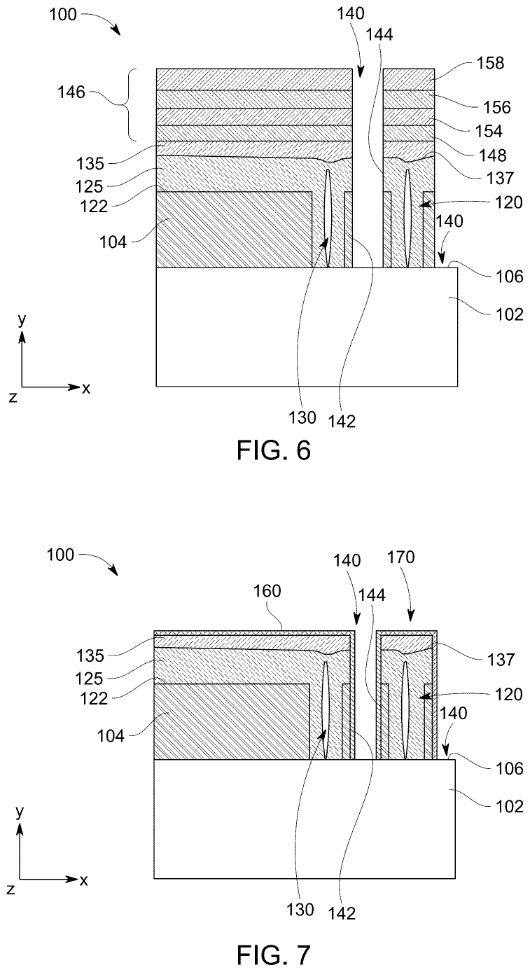

As shown in FIG. 6, a second lithography and etching process may be performed to form a second plurality of trenches 140 through the first fill material 125 and the second fill material 135. Each of the second plurality of trenches 140 may be defined by a first sidewall 142, a second sidewall 144, and the upper surface 106 of the substrate 102. A lower portion of the second plurality of trenches 140 may include exposed portions of the oxide layer 104. Prior to etching, a patterning stack 146 may be formed over the second fill material 135, the patterning stack 146 including an advanced patterning film (APF) 148 formed over an upper surface of the second fill material 135, a silicon oxynitride (SiON) layer 154 formed over the APF 148, an ARC layer 156 formed over the SiON layer 154, and a photoresist 158 formed over the ARC layer 156. In some embodiments, the second plurality of trenches 140 may be formed using a vertical etch process.

As shown in FIG. 7, the patterning stack 146 is removed, and a liner 160 may then be formed over the sensor 100, including over the second fill material 135 and along the first and second sidewalls 142, 144 of the second plurality of trenches 140. In some embodiments, the liner 160 may include a nitride (e.g., SiN), which is conformally deposited (e.g., via ALD) over the exposed surfaces of the sensor 100, resulting in a plurality of grid structures 170 of an interconnected grid array.

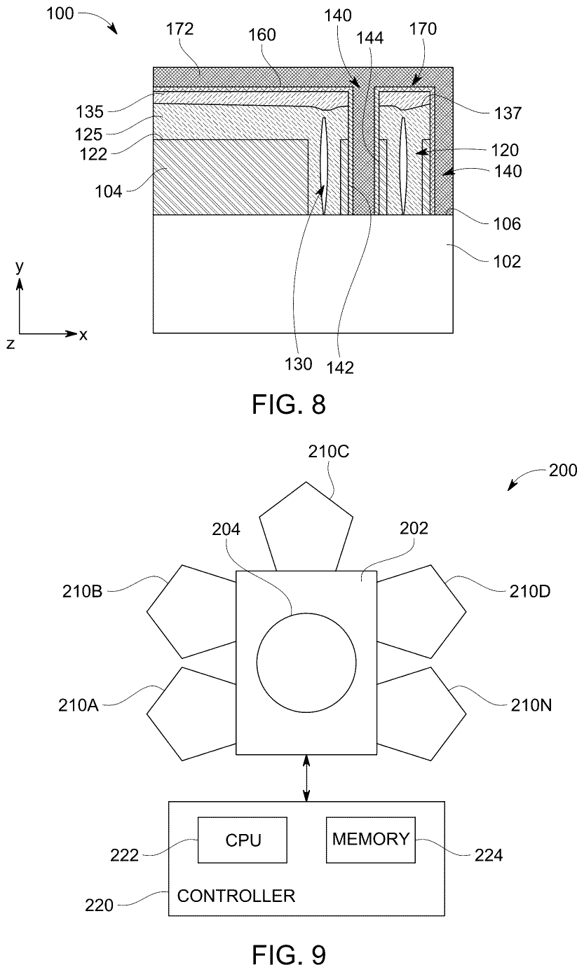

As shown in FIG. 8, a color filter layer 172 may then be formed over the liner 160, including within the second plurality of trenches 40 and over the plurality of grid structures 170. A lens layer (not shown) may then be formed over the color filter layer 172 to continue forming the sensor 100. The color filter layer 172 may include optical filters located above the photoelectric conversion elements of the substrate 102 to filter the light to be detected by the photoelectric conversion elements. For some applications, the color filter layer 172 may be structured to transmit visible light such as a predetermined wavelength range within the visible spectral range while blocking light at other wavelengths from incident light received through the lens layer. The color filter layer 172 may include a plurality of color filters, and the color filters may be formed to fill the gaps between the plurality of grid structures 170.

The plurality of grid structures 170 generally isolate or separate the space above the substrate 102 into light sensing regions in which the photoelectric conversion elements are located. Each grid structure 170 may be located at a boundary region of adjacent color filters to prevent optical crosstalk from occurring between the adjacent color filters. The grid structures 170 may be formed such that each grid structure 170 is in contact with sidewalls of the color filters.

The lens layer may include one or more micro-lenses, metasurface lenses, and/or on-chip lenses disposed over the color filter layer 172 and the grid structures 170. The plurality of micro-lenses may converge incident light beams received from the outside and may transmit the light to the color filter layer 172.

FIG. 9 shows a schematic of an example apparatus/system 200 according to implementations of the disclosure. In some implementations, the system 200 may be a cluster tool operable to perform processes necessary to form the sensor 100 described herein. Examples of processing systems that may be suitably modified in accordance with the teachings provided herein include the Endura®, Producer®, or Centura® integrated processing systems or other suitable processing systems commercially available from Applied Materials, Inc., located in Santa Clara, California. It is contemplated that other processing systems (including those from other manufacturers) may be adapted to benefit from aspects described herein.

As shown, the system 200 may include at least one central transfer station/chamber 202 and one or more robots 204 within the transfer station/chamber 202, wherein the robot 204 is operable to move a robot blade and a wafer to and from each of a plurality of processing chambers 210A-210N connected with, or positioned adjacent to, the transfer station/chamber 202. In some implementations, the processing chambers 210A-210N may support ion implantation, material deposition, material etching, thermal processing, and others. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some implementations, processing chamber 210A may be a deposition chamber operable to deposit one or more layers or features of the sensor 100. For example, the processing chamber 210A may include a material deposition tool operable to form the first fill material 125 within each of the plurality of trenches 120, and to form the second fill material 135 over the first fill material 125 using, e.g., a high-aspect-ratio process. More specifically, processing chamber 210A may be used to perform a PEHARP process including a thermal (non-plasma) CVD process followed by a plasma treatment at low pressure. Both of these processes may be performed sequentially/cyclically in process chamber 210A.

The material deposition tool may be still further operable to form the liner 160. Although non-limiting, the deposition chamber may include one or more of an atomic layer deposition chamber, a plasma enhanced atomic layer deposition chamber, a chemical vapor deposition chamber, a plasma enhanced chemical vapor deposition chamber, or a physical deposition chamber. The deposition chamber may further be an epitaxial growth deposition chamber.

In some implementations, processing chamber 210B may be an etch chamber operable to form one or more trenches, such as the first plurality of trenches 120 and/or the second plurality of trenches 140. In some implementations, processing chamber 210B may be used for wet and/or dry etch processes. In some implementations, the processing chamber 210B may be further operable to planarize one or more layers of the sensor 100, e.g., to remove the lithography layers following trench formation.

In some implementations, processing chamber 210C may be operable to perform an ion implant to the sensor 100, while processing chamber 210D may be operable to perform one or more thermal processes.

A system controller 220 is in communication with the robot 204, the transfer station/chamber 202, and the plurality of processing chambers 210A-210N. The system controller 220 can be any suitable component that can control the processing chambers 210A-210N and robot(s) 204, as well as the processes occurring within the process chambers 210A-210N. For example, the system controller 220 can be a computer including a central processor 222, memory 224, suitable circuits/logic/instructions, and storage.

Processes or instructions may generally be stored in the memory 224 of the system controller 220 as a software routine that, when executed by the processor 222, causes the processing chambers 210A-210N to perform processes of the present disclosure. The software routine may also be stored and/or executed by a second processor (not shown) that is remotely located from the hardware being controlled by the processor 222. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 222, transforms the general-purpose computer into a specific purpose computer (controller) that controls the chamber operation such that the processes are performed.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one implementation” of the present disclosure are not intended as limiting. Additional implementations may also incorporate the recited features.

Furthermore, the terms “substantial” or “substantially,” as well as the terms “approximate” or “approximately,” can be used interchangeably in some implementations, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element(s) or intervening elements may also be present. In contrast, when an element is referred to as being “directly on,” “directly over” or “directly atop” another element, no intervening elements are present.

The present disclosure is not to be limited in scope by the specific implementations described herein. Indeed, other various implementations of and modifications to the present disclosure, in addition to those described herein, will be apparent to those of ordinary skill in the art from the foregoing description and accompanying drawings. Thus, such other implementations and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of forming an image sensor, the method comprising:
depositing a first fill material within a first plurality of trenches to form a plurality of grid structures, wherein the first plurality of trenches are formed through an oxide layer formed over a substrate, wherein the first fill material is formed along a sidewall and a bottom surface of each trench of the plurality of trenches, and wherein a void is formed within the first fill material; and
forming a second plurality of trenches through the oxide layer and the first fill material.

2. The method of claim 1, further comprising forming a second fill material over the first fill material using a high-aspect-ratio process, wherein the second plurality of trenches are further formed through the second fill material.

3. The method of claim 2, wherein forming the second plurality of trenches comprises forming a trench between a set of adjacent grid structures of the plurality of grid structures.

4. The method of claim 2, further comprising forming a liner within the second plurality of trenches.

5. The method of claim 4, further comprising forming the liner over the second fill material.

6. The method of claim 1, wherein forming the first fill material comprises depositing a low-temperature oxide within the first plurality of trenches.

7. The method of claim 6 wherein forming the second fill material comprises performing a plasma-enhanced high-aspect-ratio process oxide deposition directly atop the low-temperature oxide to form the second fill material within a plurality of recesses of the first fill material present at one or more intersection areas of the first plurality of trenches.

8. The method of claim 7, wherein the plasma-enhanced high-aspect-ratio process deposition comprises:
depositing the second fill material using a thermal chemical vapor deposition; and
performing a plasma treatment following the thermal chemical vapor deposition, wherein the thermal chemical vapor deposition and the plasma treatment are performed in a same process chamber.

9. The method of claim 1, further comprising forming a color filter layer over the second fill material.

10. A method of forming a plurality of grid structures of an image sensor, the method comprising:
forming a first plurality of trenches through an oxide layer, wherein the oxide layer is formed over a substrate;
depositing a first fill material within the first plurality of trenches to form a plurality of grid structures, wherein the first fill material is formed along a sidewall and a bottom surface of each trench of the plurality of trenches, and wherein a void within one or more trenches of the first plurality of trenches is enclosed by the first fill material; and
forming a second plurality of trenches through the oxide layer and the first fill material.

11. The method of claim 10, further comprising forming a second fill material over the first fill material using a high-aspect-ratio process, wherein the second plurality of trenches are further formed through the second fill material.

12. The method of claim 11, further comprising forming a liner along a sidewall and a bottom surface of each trench of the second plurality of trenches, wherein the liner is further formed over the second fill material.

13. The method of claim 10, wherein forming the first fill material comprises depositing a low-temperature oxide within the first plurality of trenches.

14. The method of claim 13, wherein forming the second fill material comprises performing a plasma-enhanced high-aspect-ratio process oxide deposition directly atop the low-temperature oxide to form the second fill material within a plurality of recesses of the first fill material present at one or more intersection areas of the first plurality of trenches.

15. The method of claim 14, wherein the plasma enhanced high-aspect-ratio process deposition is performed at a temperature between 400° C. and 540° C.

16. A method of forming an image sensor, the method comprising:
depositing a first fill material within a first plurality of trenches to form a plurality of grid structures, wherein the first plurality of trenches define an interconnected trench array, wherein the first plurality of trenches are formed through an oxide layer formed over a substrate, wherein the first fill material is formed along a sidewall and a bottom surface of each trench of the plurality of trenches, and wherein an air gap is formed within the first fill material; and
forming a second plurality of trenches through the oxide layer and the first fill material.

17. The method of claim 16, further comprising:
forming a second fill material over the first fill material using a plasma-enhanced high-aspect-ratio process; and
forming a color filter layer over the second fill material.

18. The method of claim 17, further comprising forming a liner along a sidewall and a bottom surface of each trench of the second plurality of trenches, wherein the liner is further formed over the second fill material.

19. The method of claim 17, wherein the plasma-enhanced high-aspect-ratio process deposition comprises:
depositing the second fill material using a thermal chemical vapor deposition; and
performing a plasma treatment following the thermal chemical vapor deposition, wherein the thermal chemical vapor deposition and the plasma treatment are performed in a same process chamber.

20. The method of claim 16, wherein forming the first fill material comprises depositing a low-temperature oxide within the first plurality of trenches.
